(19) United States
(12) Patent Application Publication
(10) Pub. No.: US 2025/0060437 A1
(43) Pub. Date: Feb. 20, 2025

(54) Gradient Coil Unit with Two Cooling Circuits

(71) Applicant: Siemens Healthineers AG, Forchheim (DE)

(72) Inventors: Andreas Krug, Fürth (DE); Simon Bauer, Baunach (DE)

(73) Assignee: Siemens Healthineers AG, Forchheim (DE)

(21) Appl. No.: 18/797,763

(22) Filed: Aug. 8, 2024

(30) Foreign Application Priority Data
Aug. 14, 2023 (DE) 10 2023 207 792.2

(51) Int. Cl. G01R 33/385

(52) U.S. Cl. CPC G01R 33/3856; G01R 33/3852

(57) ABSTRACT

The disclosure relates to a gradient coil unit with a primary coil having at least one spiral conductor structure that is formed by an electrical conductor configured as a hollow conductor with a hollow region, which electrical conductor is subdivisible into two portions serially connected to one another, the electrical conductor is arranged spirally in turns in such a manner that two adjacent turns of the electrical conductor are to be associated with the two portions that differ from one another, and with two cooling circuits, wherein a cooling circuit is in each case provided for cooling a portion.

### CROSS-REFERENCE TO RELATED APPLICATIONS

The present application claims priority to and the benefit of Germany patent application no. DE 10 2023 207 792.2, filed on Aug. 14, 2023, the contents of which are incorporated herein by reference in their entirety.

### TECHNICAL FIELD

The disclosure relates to a gradient coil unit with two cooling circuits and a magnetic resonance device comprising a gradient coil unit with two cooling circuits.

### BACKGROUND

In a magnetic resonance device, the body to be examined of an object under examination, e.g. of a patient, is conventionally exposed to a relatively strong main magnetic field, for example of 1.5 or 3 tesla, with the aid of a main magnet. In the course of magnetic resonance imaging (MR imaging), gradient pulses are played out with the assistance of a gradient coil unit. Radio-frequency pulses (RF pulses), e.g. excitation pulses, are additionally emitted via a RF antenna unit by way of suitable antenna devices, which results in the nuclear spins of specific atoms resonantly excited by these RF pulses being tilted by a defined flip angle relative to the magnetic field lines of the main magnetic field. On relaxation of the nuclear spins, RF signals, known as magnetic resonance signals, are emitted which are received by suitable RF antennas and then further processed. Finally, the desired image data can be reconstructed from the raw data acquired in this manner.

A specific magnetic resonance control sequence (MR control sequence), also known as a pulse sequence, consisting of a succession of RF pulses, for example excitation pulses and refocusing pulses, together with gradient pulses to be emitted in matching, coordinated manner in different gradient axes along different spatial directions, must therefore be emitted for a particular measurement. To this end, temporally matching read-out windows are set that specify the periods in which the induced magnetic resonance signals are acquired.

A gradient coil unit conventionally comprises three primary coils and three corresponding secondary coils. The three primary coil are typically encompassed by a primary coil unit. The three secondary coils are typically encompassed by a secondary coil unit. A primary coil is typically designed to generate a magnetic field gradient in a spatial direction, e.g. within a patient accommodation zone. A magnetic field gradient is typically a first order and/or linear order magnetic field, e.g. a magnetic field, the amplitude of which increases linearly along a spatial direction. Outside of the patient accommodation zone, the effect of a primary coil is largely suppressed by a secondary coil associated with the primary coil. The secondary coil typically surrounds the corresponding primary coil and is electrically connected in series thereto. The three primary coils typically encompassed by the gradient coil unit are configured to generate magnetic field gradients in three mutually perpendicular spatial directions.

A magnetic field gradient is generated by driving the primary coil with electrical currents that have amplitudes up to several 100 A, and are subject to frequent and rapid changes in current direction with rates of rise and fall of several 100 kA/s. A magnetic field gradient is thus a time-variable magnetic field.

Greater magnetic field gradients and/or rates of rise and fall typically enable greater gradient moments and thus faster capture of raw data and/or higher-resolution image data. In particular, in the case of diffusion-weighted captures and/or of using a magnetic resonance device with a main magnetic field of greater than 3 tesla, particularly steep magnetic field gradients of up to 200 mT/m with rates of rise and fall of up to 150 T/s/m, cases of up to 200 T/s/m, etc., are desirable. However, generating such steep magnetic field gradients generates particularly large amounts of heat, which have to be dissipated by the gradient coil unit.

### SUMMARY

The object of the present disclosure is to provide a robust gradient coil unit with particularly uniform and efficient cooling. The object is achieved by the embodiments as discussed here, including the claims.

The gradient coil unit according to the disclosure comprises a primary coil having at least one spiral conductor structure that is formed by an electrical conductor configured as a hollow conductor with a hollow region, which electrical conductor is subdivisible into two portions serially connected to one another. The electrical conductor is arranged spirally in turns in such a manner that two adjacent turns of the electrical conductor are to be associated with the two portions that differ from one another. The gradient coil unit according to the disclosure comprises a first cooling circuit with a first cooling duct comprising the hollow region of a first portion of the two portions serially connected to one another, wherein the first cooling duct has a first incoupling point into the hollow region of the first portion and a first outcoupling point out of the hollow region of the first portion. The first cooling circuit is configured to pass a first cooling medium through the first cooling duct in a first direction from the first incoupling point to the first outcoupling point. The gradient coil unit according to the disclosure comprises a second cooling circuit with a second cooling duct comprising the hollow region of a second portion of the two portions serially connected to one another, wherein the second cooling duct has a second incoupling point into the hollow region of the second portion and a second outcoupling point out of the hollow region of the second portion. The second cooling circuit is configured to pass a second cooling medium through the second cooling duct in a second direction from the second incoupling point to the second outcoupling point. The first direction and second direction are oriented opposingly and the first cooling circuit and the second cooling circuit are interconnected disjunctively to one another or parallel to one another.

A spiral conductor structure typically comprises an electrical conductor with a defined geometric arrangement on a circumferential surface of a cylinder arranged within a quadrant of the gradient coil unit. The spiral conductor structure is typically of saddle-shaped configuration. The spiral conductor structure may be at least in part spiral having turns with a differing radius relative to a fixed point. The spiral conductor structure typically at least in part spirally surrounds at least one fixed point and/or an eye.

The hollow conductor may be of monolithic configuration. The hollow conductor comprises electrically conductive material that has a hollow region in the interior, which hollow region extends over the length of the hollow conductor. The electrically conductive material is configured to conduct an electrical current according to the spiral conductor structure. The hollow region is configured to receive a cooling medium, e.g. the first cooling medium and/or the second cooling medium and/or a fluid. A layer and/or ply comprising a further material can be arranged between the hollow region and the electrically conductive material. The layer and/or ply can be configured as a tube. The further material can for example comprise stainless steel.

The cross-sectional area of the hollow region may be of circular and/or rectangular and/or elliptical configuration. On the side remote from the hollow region, the cross-sectional area of the hollow conductor may have a rectangular and/or oval and/or circular shape and/or have beveled corners. The hollow conductor is typically configured in such a manner that a coolant, e.g. a fluid, can flow within the hollow region, e.g. along the length of the hollow conductor. The hollow conductor can typically have cooling medium flow through it.

The gradient coil unit is typically of hollow-cylindrical configuration. The gradient coil unit is typically configured in such a manner that the diameter of the inside of the primary coil is of any suitable dimension, such as at least 55 cm, at least 60 cm, at least 70 cm, etc. The gradient coil unit is typically configured in such a manner that a patient, e.g. a patient's abdomen, can be arranged within a hollow region surrounded and/or enclosed by the gradient coil unit. The gradient coil unit can also be configured as a local head gradient coil, wherein a patient's head can be arranged within a hollow region surrounded and/or enclosed by the gradient coil unit. If the gradient coil unit is configured as a local head gradient coil, the diameter of the inside of the primary coil may be any suitable range of dimensions, such as for instance between 35 cm and 55 cm, between 40 cm and 50 cm, etc.

The electrical conductor can be broken down and/or is subdivisible into two portions serially connected to one another and/or can consist of the two portions. The two portions may continuously transition into one another at precisely one position and are accordingly contiguous at this position. The length of the two portions may differ by less than 5%. The two portions may accordingly be denoted halves of the conductor structure.

The geometric arrangement of the electrical conductor, e.g. of the conductor structure, may be e.g. configured in such a manner that it runs spirally in turns about at least one fixed point, e.g. on a saddle form. The electrical conductor, e.g. the conductor structure, is arranged in such a manner that a plurality of turns run along a connecting line between the fixed point and an edge of the quadrant, wherein the connecting line at least in part alternately crosses a turn associated with a first portion of the two portions and a turn associated with the second portion of the two portions. A turn is to be associated with the first portion if the electrical conductor forming this turn corresponds to the first portion of the part of the electrical conductor. A turn is to be associated with the second portion if the electrical conductor forming this turn corresponds to the second portion of the part of the electrical conductor. The turns may be arranged in such a manner that, on driving the primary coil, e.g. on driving the conductor structure, an electric current in two adjacent turns is oriented identically and/or in parallel.

The first cooling circuit is typically configured to cool the first portion. The first cooling circuit is typically configured to pass the first cooling medium through the first portion, e.g. the hollow region of the hollow conductor of the first portion. The first cooling circuit typically comprises a first cooling unit and/or is connected to a main cooling unit that is configured to reduce a temperature of the first cooling medium. The second cooling circuit is typically configured to cool the second portion. The second cooling circuit is typically configured to pass the second cooling medium through the second portion, e.g. the hollow region of the hollow conductor of the second portion. The second cooling circuit typically comprises a second cooling unit and/or is connected to a main cooling unit that is configured to reduce a temperature of the second cooling medium. The gradient coil unit according to the disclosure accordingly comprises two cooling circuits, wherein a cooling circuit is in each case provided for cooling a portion.

Each cooling circuit disclosed in this description, e.g. also the first, second, and each cooling circuit described or claimed in the remainder of this description, may comprise a pump for generating a flow and/or stream of the corresponding cooling medium, e.g. through a hollow conductor. The first cooling medium and the second cooling medium may for example comprise a fluid. The first cooling medium and the second cooling medium typically have the same chemical and/or physical properties and/or comprise the same material. The first cooling medium and the second cooling medium typically differ merely in that they are each associated with different cooling circuits. The first cooling medium may correspond to the second cooling medium. The first cooling medium may differ from the second cooling medium. The pump and/or the first cooling unit and/or the second cooling unit and/or the main cooling unit are typically arranged outside of the hollow-cylindrical shape of the gradient coil unit.

According to the disclosure, the gradient coil unit is accordingly configured in such a manner that the temperature of a spiral conductor structure can be regulated by two cooling circuits and/or the power loss of a spiral conductor structure can be dissipated by way of two cooling circuits. In comparison to cooling with just one cooling circuit, when two cooling circuits are used, the length of each cooling circuit may be reduced and/or halved, whereby cooling efficiency can be improved. The lengths of the first cooling circuit and the second cooling circuit typically differ by less than 5%.

The first cooling circuit comprises the first cooling duct that comprises the hollow region of a first portion of the two portions of the electrical conductor serially connected to one another. The first cooling duct may comprise further lines and/or ducts and/or hoses configured to conduct the first cooling medium, e.g. fluids. The first incoupling point may be configured as a connection point between the hollow region of the first portion and a part of the first cooling duct not encompassed by the hollow region. The first outcoupling point may be configured as a connection point between the hollow region of the first portion and a part of the first cooling duct not encompassed by the hollow region. The direction of flow of the first cooling medium initiated by the first cooling circuit may for example correspond to the first direction defined by the course of the first portion between the first incoupling point and the first outcoupling point. The first direction may point in the longitudinal direction, e.g. along the course, of the hollow region of the first portion from the first incoupling point to the first outcoupling point.

The second cooling circuit comprises the second cooling duct that comprises the hollow region of a second portion of the two portions of the electrical conductor serially connected to one another. The second cooling duct may comprise further lines and/or ducts and/or hoses configured to conduct the second cooling medium, e.g. fluids. The second incoupling point may be configured as a connection point between the hollow region of the second portion and a part of the second cooling duct not encompassed by the hollow region. The second outcoupling point may be configured as a connection point between the hollow region of the second portion and a part of the second cooling duct not encompassed by the hollow region. The direction of flow of the second cooling medium initiated by the second cooling circuit may e.g. correspond to the second direction defined by the course of the second portion between the second incoupling point and the second outcoupling point. The second direction may point in the longitudinal direction, e.g. along the course, of the hollow region of the second portion from the second incoupling point to the second outcoupling point.

The opposing orientations of the first direction and the second direction may e.g. relate to the direction of flow of the two cooling media in two adjacent turns. The first cooling medium typically has a lower temperature at the first incoupling point than at the first outcoupling point. The second cooling medium typically has a lower temperature at the second incoupling point than at the second outcoupling point.

Using a hollow conductor in combination with two cooling circuits for a conductor structure enables particularly efficient cooling. A hollow conductor enables direct dissipation of the heat that arises. Because two cooling circuits are used instead of one, the length of the cooling circuit is halved, resulting in lower maximum temperatures. As the distance of the cooling medium from the corresponding cooling unit increases, the temperature of the cooling medium rises due to the input of heat by operation of the gradient coil unit and therefore the temperature rises along the cooling duct between the incoupling point and outcoupling point. The opposing directions of the two cooling circuits consequently enable particularly spatially uniform cooling and therefore, during operation of the gradient coil unit, the spatial temperature gradients can be kept particularly low and the temperature can be uniformly distributed in the gradient coil unit. This reduces thermal and mechanical stresses within the gradient coil unit and prevents mechanical damage in the encapsulation body of the gradient coil unit.

One embodiment of the gradient coil unit provides that, in the case of a disjunctive configuration of the first cooling circuit and the second cooling circuit:
the first cooling circuit comprises a first cooling unit and a first pump, and the first cooling duct comprises a first feed line means, which first feed line means connects the first cooling unit to the first pump in such a manner that the first cooling medium can flow through the first cooling duct, and
the second cooling circuit comprises a second cooling unit and a second pump, and the second cooling duct comprises a second feed line means, which second feed line means connects the second cooling unit to the second pump in such a manner that the second cooling medium can flow through the second cooling duct.

According to this embodiment, the first cooling circuit is typically autonomous from the second cooling circuit. The first cooling unit is configured to reduce the temperature of the first cooling medium. The second cooling unit is configured to reduce the temperature of the second cooling medium. The first cooling medium and the second cooling medium are separated from one another according to this embodiment. The first cooling medium and the second cooling medium may comprise the same fluid and/or have no differences with regard to material. The first cooling medium and the second cooling medium may comprise the same material and/or the same liquid. The first cooling medium and the second cooling medium may comprise different materials and/or different liquids.

The first pump is configured to generate a flow of the first cooling medium in the first direction through the first cooling duct. The second pump is configured to generate a flow of the second cooling medium in the second direction through the second cooling duct. The first feed line means and/or the second feed line means may comprise a hose and/or a tube.

A gradient coil unit with cooling configured in this manner is particularly robust since in particular the use of two cooling units enables particularly reliable cooling of the conductor structure.

One embodiment of the gradient coil unit provides that, in the case of parallel interconnection of the first cooling circuit and the second cooling circuit:
the gradient coil unit comprises a main cooling unit,
the first cooling medium corresponds to the second cooling medium,
the first cooling circuit comprises a first connecting means that connects the main cooling unit to the first cooling duct,
the second cooling circuit comprises a second connecting means that connects the main cooling unit to the second cooling duct.

The first connecting means and/or the second connecting means may comprise a hose and/or a tube. The first cooling circuit and the second cooling circuit can be flowed through in parallel and/or be supplied from the same reservoir comprising the first cooling medium and the second cooling medium. The first cooling medium and the second cooling medium can be jointly set in flow and/or flowing motion by a pump and/or in each case by at least one pump, and/or the first cooling medium and the second cooling medium can be cooled by a common and/or single main cooling unit.

The first cooling circuit and the second cooling circuit accordingly both have a connection to the main cooling unit and/or are interconnected in parallel thereto. This embodiment enables a particularly compact structure with just one cooling unit, which may be inexpensive.

One embodiment of the gradient coil unit provides that the distance of the first incoupling point from the second outcoupling point is smaller than the distance of the first incoupling point from the second incoupling point and/or the distance of the second incoupling point from the first outcoupling point is smaller than the distance of the first outcoupling point from the second outcoupling point. A distance can denote a spatial distance. The first incoupling point and the second outcoupling point may be arranged on adjacent turns of the first portion and the second portion. The second incoupling point and the first outcoupling point may be arranged on adjacent turns of the second portion and the first portion. This embodiment ensures that the spatial temperature distribution of the first cooling medium and the second cooling medium is particularly uniform.

One embodiment of the gradient coil unit provides that the gradient coil unit is subdivisible into four quadrants, the primary coil comprises four spiral conductor structures, wherein precisely one spiral conductor structure of the four spiral conductor structures is in each case arranged in each quadrant of the four quadrants, and the primary coil is configured to generate a magnetic field gradient in a spatial direction. The gradient coil unit and/or the primary coil is typically subdivisible into four quadrants and/or the gradient coil unit comprises four quadrants, wherein these four quadrants typically merely define four disjunctive geometric regions of the gradient coil unit. The four quadrants typically designate regions of the gradient coil unit, wherein a transition between two quadrants in each case lacks a physical and/or visible separation. The four spiral conductor structures encompassed by the primary coil may for example comprise the spiral conductor structure according to the disclosure and three further spiral conductor structures. The total of four spiral conductor structures are for example arranged symmetrically to one another, e.g. symmetrically to the cylinder axis and/or to an axis perpendicular to the cylinder axis. The four spiral conductor structures may be at least electrically interconnected to one another, e.g. at least in part electrically connected in series to one another. Such a gradient coil unit, e.g. such a primary coil, is configured to generate a particularly uniform magnetic field gradient.

One embodiment of the gradient coil unit provides that the gradient coil unit comprises at least six further cooling circuits, wherein in each case two further cooling circuits of the six further cooling circuits are configured to cool a spiral conductor structure. This embodiment accordingly provides that the primary coil is coolable by way of a total of eight cooling circuits. Two cooling circuits may be associated with each conductor structure and therefore particularly strong and uniform cooling is ensured.

One embodiment of the gradient coil unit provides that the gradient coil unit comprises a gradient amplifier unit that is connected in series to the four spiral conductor structures and is configured to drive the primary coil. A gradient amplifier unit is typically configured to output gradient pulses according to an MR control sequence, e.g. specified by a gradient control unit, to the gradient coil unit. A gradient amplifier unit can accordingly for example drive a gradient coil unit with a voltage of up to 2300 V and/or a current intensity of up to 1300 A. According to this embodiment, the primary coil for generating a magnetic field gradient in a spatial direction, e.g. in the x direction and/or y direction, is driven by way of a gradient amplifier unit. The gradient coil unit may e.g. comprise two further primary coils for generating two further magnetic field gradients in mutually perpendicular spatial directions, each of which is driven by a further gradient amplifier unit.

One embodiment of the gradient coil unit provides that the gradient coil unit comprises at least two gradient amplifier units, wherein in each case one of the two gradient amplifier units is electrically connected in series to in each case two spiral conductor structures and the two gradient amplifier units are jointly configured to drive the primary coil. According to this embodiment, the gradient coil unit comprises four spiral conductor structures and two gradient amplifier units that are jointly configured to generate a magnetic field gradient in a spatial direction. Such an embodiment enables the generation of a maximum amplitude of the magnetic field gradient of any suitable value, such as for example at least 180 mT/m, at least 200 mT/m at a slew rate of at least 180 mT/m/ms with simultaneously constant and uniform cooling, etc., which may reduce thermal and mechanical stresses and prevent mechanical damage in the encapsulation body of the gradient coil unit.

The disclosure further relates to a magnetic resonance device with a main magnet, a radio-frequency antenna unit, a gradient coil unit according to the disclosure, and a gradient control unit connected to the gradient coil unit for driving the gradient coil unit to generate a magnetic field gradient. The gradient control unit is e.g. configured to forward information according to an MR control sequence, e.g. gradient pulses, to a gradient amplifier unit.

Embodiments of the magnetic resonance device according to the disclosure are configured in a manner similar to the embodiments of the gradient coil unit according to the disclosure. The advantages of the magnetic resonance device according to the disclosure substantially correspond to the advantages of the gradient coil unit according to the disclosure that have previously been explained in detail. Features, advantages, or alternative embodiments mentioned in this connection are likewise also applicable to the other claimed subjects and vice versa.

### BRIEF DESCRIPTION OF THE DRAWINGS

Further advantages, features and details of the disclosure are revealed by the exemplary embodiments described below with reference to the drawings in which:

FIG. 1 illustrates a schematic representation of a first embodiment of an example conductor structure with two cooling circuits of a gradient coil unit according to the disclosure in a first view;

FIG. 2 illustrates a schematic representation of a first embodiment of an example conductor structure with two cooling circuits of a gradient coil unit according to the disclosure in a second view;

FIG. 3 illustrates a schematic representation of a second embodiment of an example gradient coil unit with two disjunctive cooling circuits;

FIG. 4 illustrates a schematic representation of a third embodiment of an example gradient coil unit with two cooling circuits interconnected in parallel;

FIG. 5 illustrates a schematic representation of a fourth embodiment of an example gradient coil unit with a gradient amplifier unit;

FIG. 6 illustrates a schematic representation of a fifth embodiment of an example gradient coil unit with two gradient amplifier units; and

FIG. 7 illustrates a schematic representation of an example magnetic resonance device, in accordance with an embodiment of the disclosure.

### DETAILED DESCRIPTION OF THE DISCLOSURE

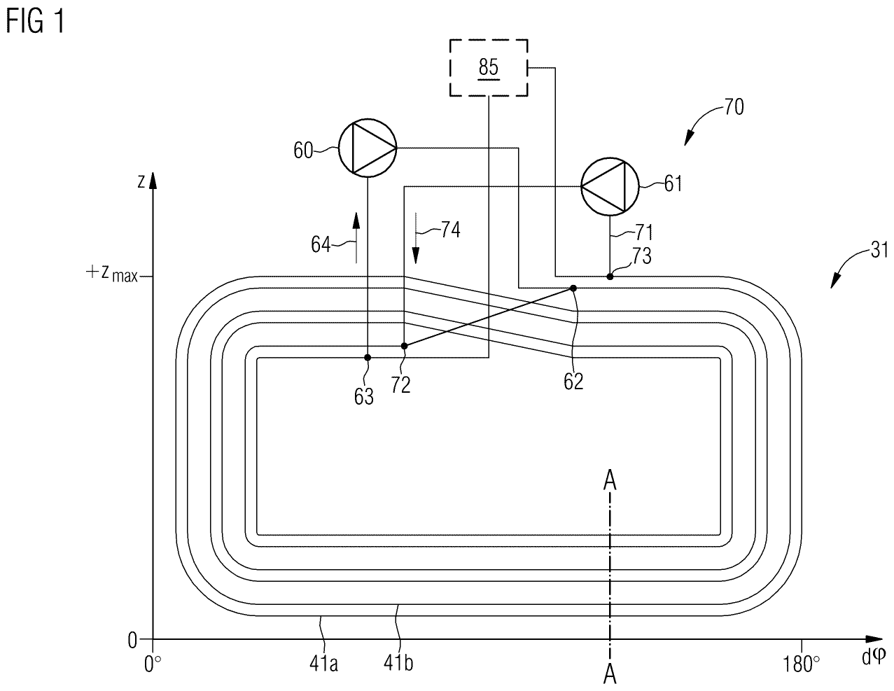

FIG. 1 is a schematic representation of a first embodiment of a conductor structure 31 with two cooling circuits 60, 70 of a gradient coil unit 19 according to the disclosure in a first view. The gradient coil unit 19 comprises a primary coil with a spiral conductor structure 31. The gradient coil unit 19 is typically subdivisible into four quadrants and the primary coil comprises four spiral conductor structures, wherein precisely one spiral conductor structure 31 of the four spiral conductor structures is in each case arranged in each quadrant of the four quadrants, and the primary coil is configured to generate a magnetic field gradient in a spatial direction. FIG. 1 is a schematic representation of one quadrant of the gradient coil unit 19, e.g. of the primary coil. A quadrant is typically defined by z=[0; +/−zmax] and dφ=[0; +/−180°]. +/−zmax typically in each case defines a longitudinal end of the gradient coil unit 19 in the longitudinal direction z. A spiral conductor structure 31 is in each case arranged in one of the four quadrants. The spiral conductor structure 31 is accordingly delimited to one quadrant.

The spiral conductor structure 31 is formed by an electrical conductor configured as a hollow conductor with a hollow region. The electrical conductor is subdivisible into two portions 41a, 41b serially connected to one another and arranged spirally in turns in such a way that two adjacent turns of the electrical conductor are to be associated with the two portions 41a, 41b that differ from one another.

The gradient coil unit 19 comprises a first cooling circuit 70 with a first cooling duct 71 comprising the hollow region of a first portion 41a of the two portions 41a, 41b serially connected to one another, wherein the first cooling duct 71 has a first incoupling point 72 into the hollow region of the first portion 41a and a first outcoupling point 73 out of the hollow region of the first portion 41a. The first cooling circuit 70 is configured to pass a first cooling medium through the first cooling duct 71 in a first direction 74 from the first incoupling point 72 to the first outcoupling point 73.

The gradient coil unit 19 comprises a second cooling circuit 60 with a second cooling duct 61 comprising the hollow region of a second portion 41a of the two portions 41a, 41b serially connected to one another, wherein the second cooling duct 61 has a second incoupling point 62 into the hollow region of the second portion 41b and a second outcoupling point 63 out of the hollow region of the second portion 41b. The second cooling circuit 60 is configured to pass a second cooling medium through the second cooling duct 61 in a second direction 64 from the second incoupling point 62 to the second outcoupling point 63. The first direction 74 and the second direction 64 are oriented opposingly (e.g. in opposite directions to one another). In the case shown, the first cooling circuit 70 and the second cooling circuit 60 are configured disjunctively (separately) to one another.

According to the embodiment shown, the first incoupling point 72 and the second outcoupling point 63 are arranged on adjacent turns of the first portion 41a and the second portion 41b. In addition, the second incoupling point 62 and the first outcoupling point 73 are arranged on adjacent turns of the second portion 41b and the first portion 41a. The distance of the first incoupling point 72 from the second outcoupling point 63 is accordingly smaller than the distance of the first incoupling point 72 from the second incoupling point 62. In addition, the distance of the second incoupling point 62 from the first outcoupling point 73 is smaller than the distance of the first outcoupling point 73 from the second outcoupling point 63.

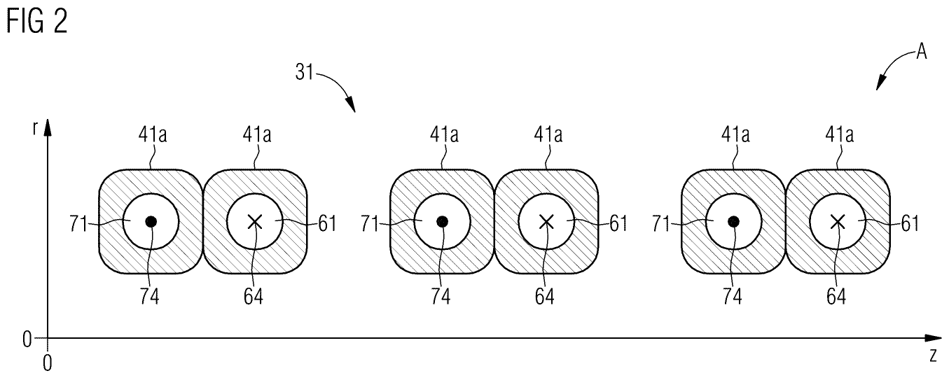

FIG. 2 is a schematic representation of a first embodiment of a conductor structure 31 with two cooling circuits of a gradient coil unit 19 according to the disclosure in a second view A. The second view A corresponds to the cross-sectional area, indicated A in FIG. 1, through the conductor structure 31. This e.g. clarifies the opposing orientation of the first direction 74 and the second direction 64 in adjacent turns of the two portions 41a, 41b.

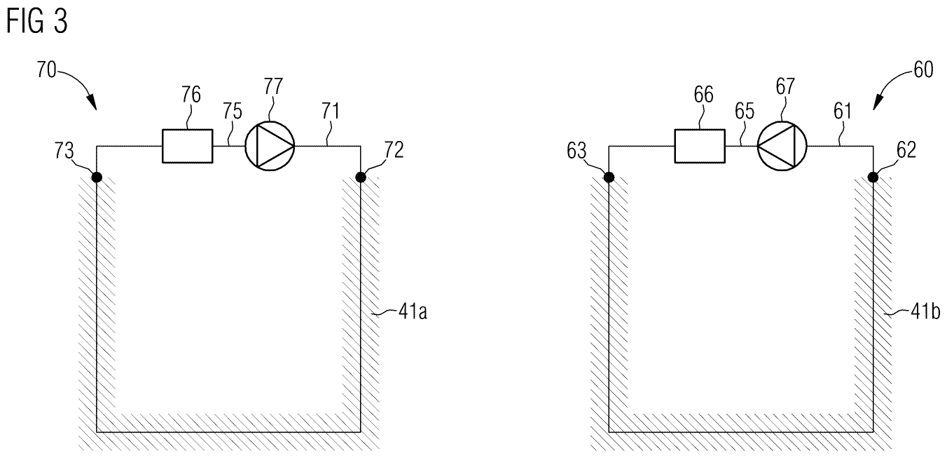

FIG. 3 is a schematic representation of a second embodiment of a gradient coil unit with two disjunctive cooling circuits with a disjunctive (e.g. separate) configuration of the first cooling circuit 70 and the second cooling circuit 60.

The first cooling circuit 70 comprises a first cooling unit 76 and a first pump 77 and the first cooling duct 71 comprises a first feed line means 75, which first feed line means 75 connects the first cooling unit 76 to the first pump 77 in such a manner that the first cooling medium can flow through the first cooling duct 71 e.g. in the first direction 74. The second cooling circuit 60 comprises a second cooling unit 66 and a second pump 67. The second cooling duct 61 comprises a second feed line means 65, which second feed line means 65 connects the second cooling unit 66 to the second pump 67 in such a manner that the second cooling medium can flow through the second cooling duct 61 e.g. in the second direction 64. The first feed line means 75 and the second feed line means 65 may be implemented as any suitable materials for this purpose, such as rigid or flexible hollow tubing, solid materials, etc., made of any suitable type of material, such as polymer or metal for instance.

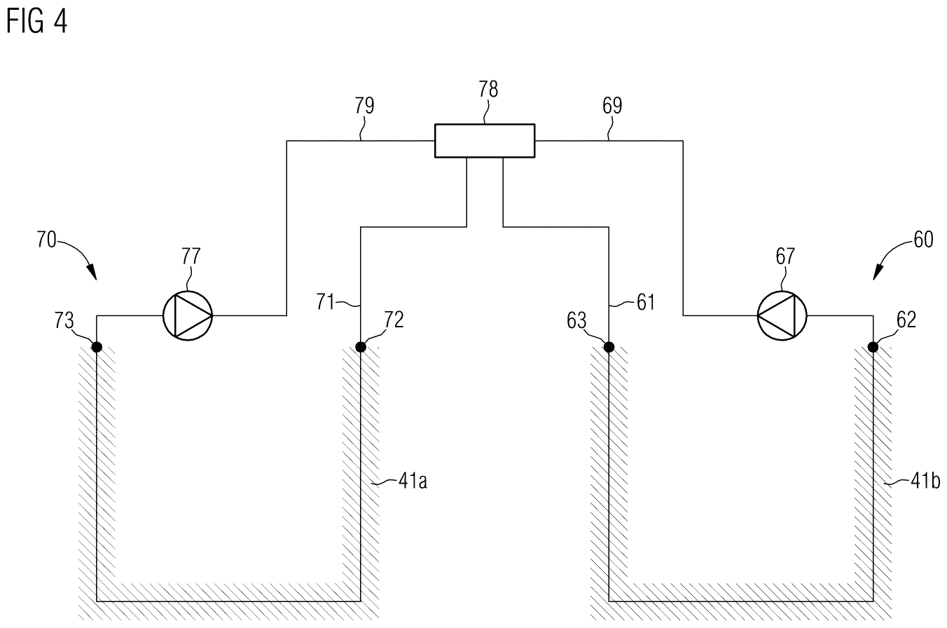

FIG. 4 is a schematic representation of a third embodiment of a gradient coil unit with two cooling circuits interconnected in parallel, e.g. with parallel interconnection of the first cooling circuit 70 and the second cooling circuit 60.

The gradient coil unit 19 comprises a main cooling unit 78. The first cooling circuit 70 comprises a first connecting means 79 that connects the main cooling unit to the first cooling duct 71. The second cooling circuit 61 comprises a second connecting means 69 that connects the main cooling unit 78 to the second cooling duct 61. The first connecting means 79 and the second connecting means 69 may be implemented as any suitable materials for this purpose, such as rigid or flexible hollow tubing, solid materials, etc., made of any suitable type of material, such as polymer or metal for instance.

The first cooling medium and the second cooling medium may be fed from a reservoir of the main cooling unit 78, and therefore the first cooling medium and the second cooling medium may have an identical consistency and/or differ merely in the use thereof in different cooling circuits.

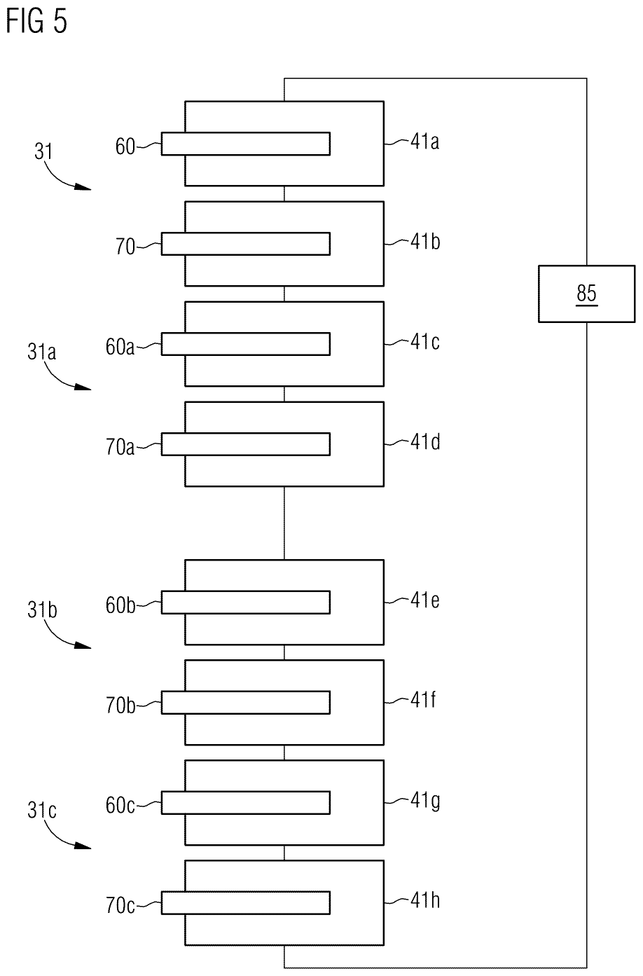

FIG. 5 is a schematic representation of a fourth embodiment of a gradient coil unit 19 with a gradient amplifier unit 85. According to this embodiment, the primary coil comprises four spiral conductor structures 31, 31a, 31b, 31c, wherein precisely one spiral conductor structure of the four spiral conductor structures 31, 31a, 31b, 31c is in each case arranged in each quadrant of the four quadrants, and the primary coil is configured to generate a magnetic field gradient in a spatial direction.

In addition to the first cooling circuit 70 and the second cooling circuit 60, the gradient coil unit 19 comprises six further cooling circuits 60a, 60b, 60c, 70a, 70b, 70c, wherein in each case two further cooling circuits of the six further cooling circuits 60a, 60b, 60c, 70a, 70b, 70c are configured to cool one spiral conductor structure of the three spiral conductor structures 31a, 31b, 31c. The four spiral conductor structures 31, 31a, 31b, 31c are in each case subdivisible into two portions 41a, 41b, 41c, 41d, 41c, 41f, 41g, 41h serially connected to one another, wherein in each case one cooling circuit of cooling circuits 60, 70, 60a, 60b, 60c, 70a, 70b, 70c is in each case associated with one of the portions 41a, 41b, 41c, 41d, 41e, 41f, 41g, 41h serially connected to one another. The gradient coil unit 19 comprises the gradient amplifier unit 85 that is connected in series to the four spiral conductor structures 31, 31a, 31b, 31c and is configured to drive the primary coil.

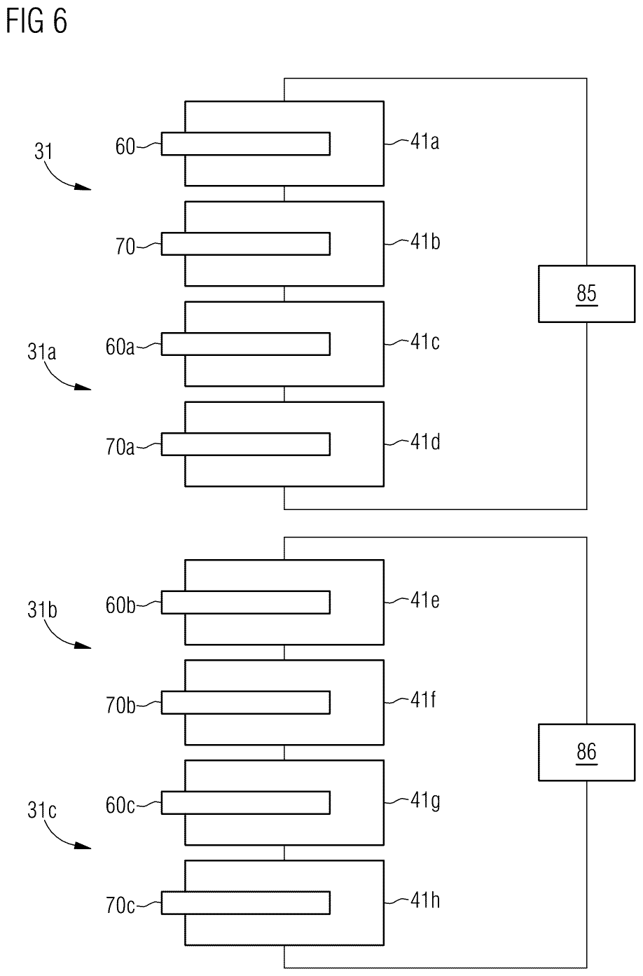

FIG. 6 is a schematic representation of a fifth embodiment of a gradient coil unit with two gradient amplifier units. This differs from the fourth embodiment shown in FIG. 5 in that the gradient coil unit 19 comprises two gradient amplifier units 85, 86, wherein in each case one of the two gradient amplifier units 85, 86 is electrically connected in series to in each case two spiral conductor structures 31, 31a and/or 31b, 31c and the two gradient amplifier units 85, 86 are jointly configured to drive the primary coil.

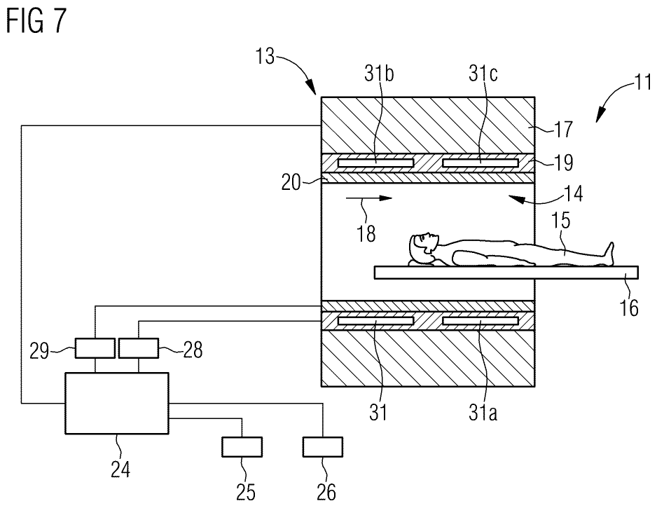

FIG. 7 shows a magnetic resonance device 11 according to the disclosure. The magnetic resonance device 11 comprises a detector unit 13 with a main magnet 17 for generating a strong and constant main magnetic field 18 in parallel to the longitudinal direction. The magnetic resonance device 11 additionally has a cylindrical patient accommodation zone 14 for accommodating a patient 15, wherein the patient accommodation zone 14 is cylindrically enclosed in a circumferential direction by the detector unit 13. The patient 15 can be advanced into the patient accommodation zone 14 by way of a patient positioning apparatus 16 of the magnetic resonance device 11. To this end, the patient positioning apparatus 16 has a patient table that is arranged movably within the magnetic resonance device 11. The detector unit 13 further comprises a RF antenna unit 20 which in the case shown is configured as a body coil fixedly integrated into the magnetic resonance device 11 and a radio-frequency antenna control unit 29 for exciting a polarization that is established in the main magnetic field 18 generated by the main magnet 17. The RF antenna unit 20 is driven by the radio-frequency antenna control unit 29 and emits RF pulses into an investigation chamber that is substantially formed by the patient accommodation zone 14.

The detector unit 13 further has a gradient coil unit 19 according to the disclosure that is used for spatial encoding during imaging. The gradient coil unit 19 comprises a hollow-cylindrical primary coil surrounding the cylindrical patient accommodation zone 14 in the longitudinal direction, which primary coil is configured to generate a magnetic field gradient in a first spatial direction. The primary coil comprises four spiral conductor structures 31, 31a, 31b, 31c, wherein precisely one spiral conductor structure of the four spiral conductor structures is in each case arranged in each quadrant of the four quadrants.

The gradient coil unit 19 is driven by way of a gradient control unit 28 to generate a magnetic field gradient in the first spatial direction. The gradient control unit 28 is typically configured to drive all the gradient amplifier units 85, 86 encompassed by the gradient coil unit 19. To this end, the gradient control unit 28 is typically connected to the gradient amplifier units 85, 86 and the latter are configured to generate an electrical voltage and/or an electrical current, e.g. gradient pulses according to an MR control sequence, as for example specified by the gradient control unit 28, in the gradient coil unit 19. Reference is in particular made to FIGS. 1 to 6 for a detailed presentation of the gradient coil unit 19.

The magnetic resonance device 11 comprises a control unit 24 for controlling the main magnet 17, the gradient control unit 28 and the RF antenna control unit 29. The control unit 24 centrally controls the magnetic resonance device 11, such as for example the performance of MR control sequences. The magnetic resonance device 11 has a display unit 25. The magnetic resonance device 11 furthermore has an input unit 26, by way of which information and/or control parameters may be input by a user during a measurement procedure. The control unit 24 may comprise the gradient control unit 28 and/or radio-frequency antenna control unit 29 and/or the display unit 25 and/or the input unit 26.

The illustrated magnetic resonance device 11 may of course comprise further components which magnetic resonance devices 11 usually have. A general mode of operation of a magnetic resonance device 11 is additionally known to a person skilled in the art and therefore no detailed description of the further components is provided.

Although the disclosure has been illustrated and described in greater detail with reference to exemplary embodiments, the disclosure is not restricted by the disclosed examples and other variations may be derived therefrom by a person skilled in the art without going beyond the scope of protection of the disclosure. Independent of the grammatical term usage, individuals with male, female or other gender identities are included within the term.

The various components described herein may be referred to as “units,” for instance with respect to FIG. 7. Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units or subunits, as applicable and relevant, may alternatively be referred to herein as “circuitry,” “controllers,” “processors,” or “processing circuitry,” or alternatively as noted herein.

What is claimed is:

1. A gradient coil unit, comprising:
a primary coil comprising a spiral conductor structure formed by an electrical conductor configured as a hollow conductor with a hollow region,
wherein the electrical conductor comprises two or more portions serially connected to one another, and
wherein the electrical conductor is arranged spirally in turns such that two adjacent turns of the electrical conductor are associated with two of the two or more portions that differ from one another;
a first cooling circuit having a first cooling duct comprising the hollow region of a first portion of the two or more portions,
wherein the first cooling duct has a first incoupling point into the hollow region of the first portion and a first outcoupling point out of the hollow region of the first portion that is configured to pass a first cooling medium through the first cooling duct in a first direction from the first incoupling point to the first outcoupling point; and
a second cooling circuit having a second cooling duct comprising the hollow region of a second portion of the two or more portions,
wherein the second cooling duct has a second incoupling point into the hollow region of the second portion and a second outcoupling point out of the hollow region of the second portion that is configured to pass a second cooling medium through the second cooling duct in a second direction from the second incoupling point to the second outcoupling point,
wherein the first direction and the second direction are oriented opposingly, and
wherein the first cooling circuit and the second cooling circuit are interconnected separately from one another or parallel to one another.

2. The gradient coil unit as claimed in claim 1, wherein for a separate configuration of the first cooling circuit and the second cooling circuit:
the first cooling circuit comprises a first cooling unit and a first pump;
the first cooling duct comprises a first feed line means that connects the first cooling unit to the first pump such that the first cooling medium flows through the first cooling duct;
the second cooling circuit comprises a second cooling unit and a second pump; and
the second cooling duct comprises a second feed line means that connects the second cooling unit to the second pump such that the second cooling medium flows through the second cooling duct.

3. The gradient coil unit as claimed in claim 1, wherein for a parallel interconnection of the first cooling circuit and the second cooling circuit:
the gradient coil unit comprises a main cooling unit;
the first cooling medium comprises the second cooling medium;
the first cooling circuit comprises a first connecting means that connects the main cooling unit to the first cooling duct; and
the second cooling circuit comprises a second connecting means that connects the main cooling unit to the second cooling duct.

4. The gradient coil unit as claimed in claim 1, wherein a distance of the first incoupling point from the second outcoupling point is less than a distance of the first incoupling point from the second incoupling point.

5. The gradient coil unit as claimed in claim 4, wherein a distance of the second incoupling point from the first outcoupling point is less than a distance of the first outcoupling point from the second outcoupling point.

6. The gradient coil unit as claimed in claim 1, wherein a distance of the second incoupling point from the first outcoupling point is less than a distance of the first outcoupling point from the second outcoupling point.

7. The gradient coil unit as claimed in claim 1, wherein:
the gradient coil unit comprises four quadrants,
the primary coil comprises four spiral conductor structures,
each one of the four spiral conductor structures is arranged in each respective quadrant of the four quadrants, and
the primary coil is configured to generate a magnetic field gradient in a spatial direction.

8. The gradient coil unit as claimed in claim 7,
wherein the gradient coil unit comprises six further cooling circuits, and
wherein each pair of two further cooling circuits of the six further cooling circuits are configured to cool a respective spiral conductor structure.

9. The gradient coil unit as claimed in claim 7, wherein the gradient coil unit comprises a gradient amplifier unit that is connected in series to the four spiral conductor structures and is configured to drive the primary coil.

10. The gradient coil unit as claimed in claim 7,
wherein the gradient coil unit comprises at least two gradient amplifier units,
wherein each of the at least two gradient amplifier units is electrically connected in series to two spiral conductor structures of the four spiral conductor structures, and
the two gradient amplifier units are jointly configured to drive the primary coil.

11. A magnetic resonance device, comprising:
a main magnet;
a gradient coil unit, comprising:
a primary coil comprising a spiral conductor structure formed by an electrical conductor configured as a hollow conductor with a hollow region,
wherein the electrical conductor comprises two or more portions serially connected to one another, and
wherein the electrical conductor is arranged spirally in turns such that two adjacent turns of the electrical conductor are associated with two of the two or more portions that differ from one another;
a first cooling circuit having a first cooling duct comprising the hollow region of a first portion of the two or more portions,
wherein the first cooling duct has a first incoupling point into the hollow region of the first portion and a first outcoupling point out of the hollow region of the first portion that is configured to pass a first cooling medium through the first cooling duct in a first direction from the first incoupling point to the first outcoupling point; and
a second cooling circuit having a second cooling duct comprising the hollow region of a second portion of the two or more portions,
wherein the second cooling duct has a second incoupling point into the hollow region of the second portion and a second outcoupling point out of the hollow region of the second portion that is configured to pass a second cooling medium through the second cooling duct in a second direction from the second incoupling point to the second outcoupling point,
wherein the first direction and the second direction are oriented opposingly, and
wherein the first cooling circuit and the second cooling circuit are interconnected separately from one another or parallel to one another; and
a gradient control unit connected to the gradient coil unit, the gradient control unit configured to drive the gradient coil unit to generate a magnetic field gradient.
